(19) United States
(12) Patent Application Publication
(10) Pub. No.: US 2026/0032854 A1
(43) Pub. Date: Jan. 29, 2026

(54) COOLING CABINET AND FAN MODULE THEREOF

(71) Applicant: DELTA ELECTRONICS, INC., Taoyuan City (TW)

(72) Inventors: Li-An Chung, Taoyuan City (TW); Cih-Ping Wang, Taoyuan City (TW); Sheng-Chi Wu, Taoyuan City (TW); Yu-Cheng Chang, Taoyuan City (TW); Chung-Ju Tsai, Taoyuan City (TW)

(21) Appl. No.: 19/274,324

(22) Filed: Jul. 18, 2025

Related U.S. Application Data
(60) Provisional application No. 63/676,560, filed on Jul. 29, 2024.

(30) Foreign Application Priority Data
Jan. 8, 2025 (CN) 202520037980.6

(51) Int. Cl. H05K 7/20

(52) U.S. Cl. CPC H05K 7/20172; H05K 7/20263; H05K 7/20763

(57) ABSTRACT

A cooling cabinet and a fan module thereof are disclosed. The fan module is detachably disposed on a mounting base including a square window, an alignment platform and an engagement hole. The alignment platform is disposed at two diagonally opposite corners, and the engagement hole is disposed on the alignment platform. The fan module includes a square housing, an alignment recess and an engagement component. The alignment recess is disposed at two diagonally opposite corners, and recessed from a rear side to a front side of the square housing. The engagement component runs through the alignment recess. When the alignment recess and the alignment platform are aligned, the fan module is accommodated in the mounting base. When the alignment recess and the alignment platform are matched, the engagement component is allowed rotating to engage with the engagement hole, so that the fan module is locked on the mounting base.

### CROSS-REFERENCE TO RELATED APPLICATION

This application claims the benefit of U.S. Provisional Application No. 63/676,560 filed on Jul. 29, 2024, and entitled “AIR ASSISTED LIQUID COOLING SYSTEM WITH TOOLLESS SANITARY TRI-CLAMP DESIGN, Y-SHAPED TUBE DESIGN AND FAN BLIND INSERTION DESIGN”. This application claims priority to China Patent Application No. 202520037980.6, filed on Jan. 8, 2025. The entireties of the above-mentioned patent applications are incorporated herein by reference for all purposes.

### FIELD OF THE INVENTION

The present disclosure relates to a cooling system, and more particularly to a cooling cabinet and a fan module thereof, wherein the fan module has the structure with a modular design to simplify the maintenance of the cooling cabinet or the replacement of the fan module, and it allows performing the positioning, the power connection and the installation and fixation of the assembly without tools, so as to reduce the replacement time sufficiently.

### BACKGROUND OF THE INVENTION

At present, as the CPU and GPU in the server generate more and more heat, the traditional air cooling method is no longer adequate. Therefore, the liquid cooling system is gradually used instead of the air cooling system. The liquid cooling system is usually used with a cold plate in the server for heat dissipation. The cold plate includes a micro-channel structure for heat exchange. During operation, the heat generated by the coolant still needs to be dissipated over a large area through the multiple fans cooperated with the heat exchanger. Therefore, the fan can be considered an important element in an air-assisted liquid cooling cabinet.

Generally speaking, the number of fans used in the air-assisted liquid cooling cabinet is very large, and the probability of failure is high. Therefore, the maintenance and the replacement of the fan modules are often required. However, the products currently on the market require the use of additional replacement tools to replace the fan module. The replacement time is long and requires more working hours and manpower.

Therefore, there is a need of providing a cooling cabinet and a fan module thereof. The fan module has the structure with a modular design to simplify the maintenance of the cooling cabinet or the replacement of the fan module, and it allows performing the positioning, the power connection and the installation and fixation of the assembly without tools, so as to reduce the replacement time sufficiently, and obviate the drawbacks encountered by the prior arts.

### SUMMARY OF THE INVENTION

An object of the present disclosure is to provide a cooling cabinet and a fan module thereof. The fan module has the structure with a modular design to simplify the maintenance of the cooling cabinet or the replacement of the fan module, and it allows performing the positioning, the power connection and the installation and fixation of the assembly without tools, so as to reduce the replacement time sufficiently.

Another object of the present disclosure is to provide a cooling cabinet and a fan module thereof. A plurality of fan modules with modular design structures allow simple and fast installation in a plurality of mounting bases on the rear panel of the cooling cabinet, and corresponding to the heat exchanger in the cabinet to realize the application of the air-assisted liquid cooling cabinet. A pair of handles are disposed on a front side of the square housing of each fan module, so that the fan module can be easily lifted, installed or removed. An alignment recess is disposed at two diagonally opposite corners of the square housing, and spatially corresponding to the alignment platform of the mounting base, so that the fan module can be placed into the corresponding mounting base. In addition, the engagement component includes a quarter turn lock, which runs through the front side of the square housing to the alignment recess and corresponds to the engagement hole on the alignment platform. When the fan module is accommodated into the corresponding mounting base through the handles by the user, it allows the user turning the engagement component on the front side of the square housing, for example 90 degrees, or pressing down the engagement component to be engaged or loosened with the engagement hole. Then the fan module is firmly locked on the corresponding mounting base or detached from the mounting base. The alignment recess is formed by case trimming of the square housing, and the square housing allows to include any shape of the chamfered corners corresponding to the alignment platform. It prevents the user from damaging the fan module due to the wrong installation direction when placing the fan module into the mounting base. In addition, the pairing of the alignment recess and the alignment platform can be realized in a recessed push-in manner, and it makes positioning easier. The electrical connection design between the fan module and the mounting base of the cabinet is implemented by using the quick connector (blind plug) terminals. During installation, the user holds the handles and pushes the fan module into the mounting base. At the same time, the quick connector (blind plug) also completes the electrical connection. There is no need to manually connect the power or signal lines. In addition, the male terminal of the quick connector is designed to allow slight movement, and it helps to avoid damage caused by tolerances. In this way, the plurality modular fan modules on the cooling cabinet can be easily and quickly installed and disassembled without the use of tools. The present disclosure includes the industrial applicability and the inventive steps.

In accordance with an aspect of the present disclosure, a cooling cabinet is provided and includes a cabinet, a plurality of fan modules and a heat exchanger. The cabinet includes a rear panel and a plurality of mounting bases, wherein the plurality of mounting bases are arranged in an array on the rear panel and in communication from an exterior of the cabinet to an internal space of the cabinet, wherein each of the plurality of mounting bases includes a square window, an alignment platform and an engagement hole, the alignment platform is disposed at two diagonally opposite corners of the square window, and the engagement hole is correspondingly disposed on the alignment platform. The plurality of fan modules are detachably disposed on the plurality of mounting bases, wherein the each of the plurality of fan modules includes a square housing, an alignment recess and an engagement component, wherein the square housing and the square window are matched to each other, the alignment recess is disposed at two diagonally opposite corners of the square housing, and recessed from a rear side to a front side of the square housing, the alignment recess is spatially corresponding to the alignment platform of the mounting base, and the engagement component runs through the alignment recess from the front side of the square housing, wherein when the alignment recess and the alignment platform are aligned with each other, the fan module is allowed to be accommodated in a corresponding one of the plurality of mounting bases along a docking direction, wherein when the alignment recess and the alignment platform are matched with each other, the engagement component is allowed rotating to engage with the engagement hole, so that the fan module is locked on the corresponding one of the plurality of mounting bases. The heat exchanger is disposed in the cabinet; wherein when the plurality of fan modules are enabled, gas is transported from the rear panel into the internal space of the cabinet to cool the heat exchanger.

In an embodiment, the cooling cabinet is an air-assisted liquid cooling cabinet used in a data center.

In an embodiment, each of the plurality of fan modules includes a pair of handles disposed on a front side of the square housing and parallel to two lateral sides of the square housing.

In an embodiment, the docking direction is perpendicular to a front side of the square housing, wherein when the plurality of fan modules are accommodated in the plurality of mounting bases along the docking direction, respectively, the front side of the square housing is coplanar with the square window.

In an embodiment, the engagement component is a quarter turn lock with an engaging tail end, wherein a length of the engaging tail end is shorter than a length of the engagement hole and greater than a width of the engagement hole.

In an embodiment, when the alignment recess is aligned with the alignment platform and allows the fan module to be accommodated in the corresponding one of the plurality of mounting bases along the docking direction, the engagement component is rotated to an unlocking position, and the engaging tail end allows passing through the engagement hole to make the alignment recess butt the alignment platform.

In an embodiment, when the fan module is accommodated in the corresponding one of the plurality of mounting bases along the docking direction and the alignment recess butts the alignment platform, the engagement component is rotated from the unlocking position to a locking position, and the engaging tail end and the engagement hole are interfered with each other to lock the fan module in the corresponding one of the plurality mounting bases.

In an embodiment, the alignment recess is formed by two opposite chamfered corners of the square housing.

In an embodiment, each of the plurality of mounting bases includes a first connector disposed at a corner of the square window, each of the plurality of fan modules includes a second connector disposed at a rear side of the square housing, and the second connector is spatially corresponding to the first connector, wherein when the fan module is accommodated in the corresponding one of the plurality of mounting bases along the docking direction, the first connector and the second connector are connected to form an electrical connection.

In an embodiment, the first connector and the second connector are respectively a quick connector male terminal and a quick connector female terminal matched with each other.

In accordance with another aspect of the present disclosure, a fan module is provided and detachably disposed on a mounting base. The mounting base includes a square window, an alignment platform and an engagement hole, the alignment platform is disposed at two diagonally opposite corners of the square window, the engagement holes are disposed on the alignment platform, and the fan module includes a square housing, an alignment recess and an engagement component. The square housing is matched with the square window. The alignment recess is disposed at two diagonally opposite corners of the square housing, and recessed from a rear side to a front side of the square housing, and the alignment recess is spatially corresponding to the alignment platform of the mounting base. The engagement component runs through the alignment recess from the front side of the square housing, wherein when the alignment recess and the alignment platform are aligned with each other, the fan module is allowed to be accommodated in the mounting base along a docking direction, wherein when the alignment recess and the alignment platform are matched with each other, the engagement component is allowed rotating to engage with the engagement hole, so that the fan module is locked on the mounting base.

In an embodiment, the fan module includes a pair of handles disposed on a front side of the square housing and parallel to two lateral sides of the square housing.

In an embodiment, the docking direction is perpendicular to a front side of the square housing, wherein when the fan module is accommodated in the mounting base along the docking direction, the front side of the square housing is coplanar with the square window.

In an embodiment, the engagement component is a quarter turn lock with an engaging tail end, wherein a length of the engaging tail end is shorter than a length of the engagement hole and greater than a width of the engagement hole.

In an embodiment, when the alignment recess is aligned with the alignment platform and allows the fan module to be accommodated in the mounting base along the docking direction, the engagement component is rotated to an unlocking position, and the engaging tail end allows passing through the engagement hole to make the alignment recess butt the alignment platform.

In an embodiment, when the fan module is accommodated in the mounting base along the docking direction and the alignment recess butts the alignment platform, the engagement component is rotated from the unlocking position to a locking position, and the engaging tail end and the engagement hole are interfered with each other to lock the fan module in the mounting base.

In an embodiment, the alignment recess is formed by two opposite chamfered corners of the square housing.

In an embodiment, the mounting base includes a first connector disposed at a corner of the square window, the fan module includes a second connector disposed at a rear side of the square housing, and the second connector is spatially corresponding to the first connector, wherein when the fan module is accommodated in the mounting base along the docking direction, the first connector and the second connector are connected to form an electrical connection.

In an embodiment, the first connector and the second connector are respectively a quick connector male terminal and a quick connector female terminal matched with each other.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a perspective structural view illustrating a cooling cabinet according to an embodiment of the present disclosure;

FIG. 2 is a perspective structural view illustrating the fan module corresponding to the mounting base according to the embodiment of the present disclosure;

FIG. 3 is an exploded view illustrating the fan module according to the embodiment of the present disclosure;

FIG. 4 is a perspective structural view illustrating the fan module according to the embodiment of the present disclosure and taken from the rear perspective;

FIG. 5 is a front view illustrating the fan module according to the embodiment of the present disclosure;

FIG. 6 is a front view illustrating the mounting base according to the embodiment of the present disclosure;

FIG. 7 is a front view illustrating the fan module accommodated in the mounting base and the engagement component is rotated to the unlocking position according to the embodiment of the present disclosure;

FIG. 8 is a rear view illustrating the fan module accommodated in the mounting base and the engagement component is rotated to the unlocking position according to the embodiment of the present disclosure;

FIG. 9 is a front view illustrating the fan module accommodated in the mounting base and the engagement component is rotated to the locking position according to the embodiment of the present disclosure; and

FIG. 10 is a rear view illustrating the fan module accommodated in the mounting base and the engagement component is rotated to the locking position according to the embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “top,” “bottom,” “front,” “rear” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

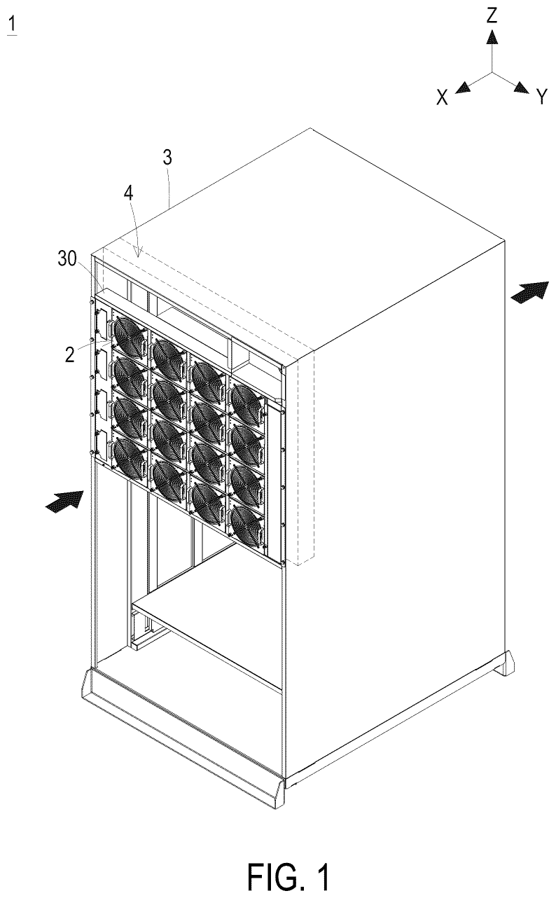

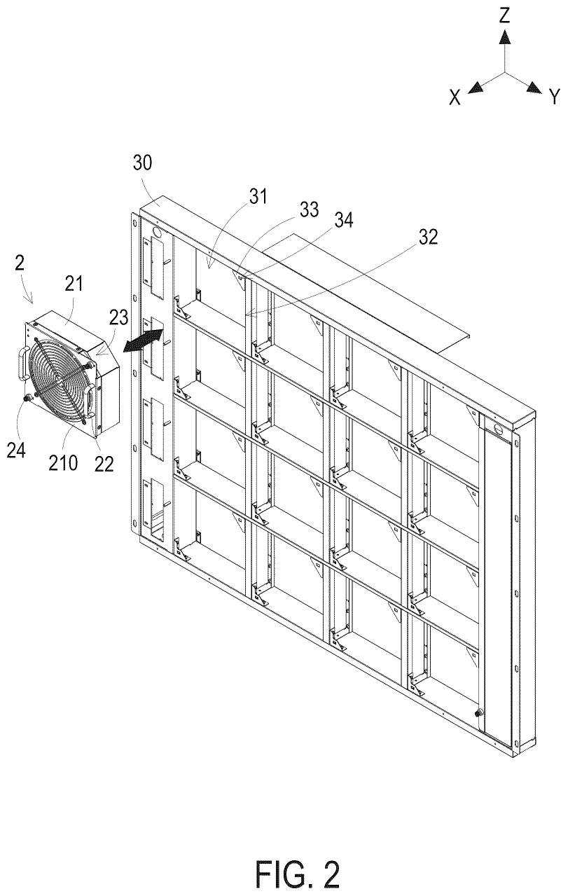

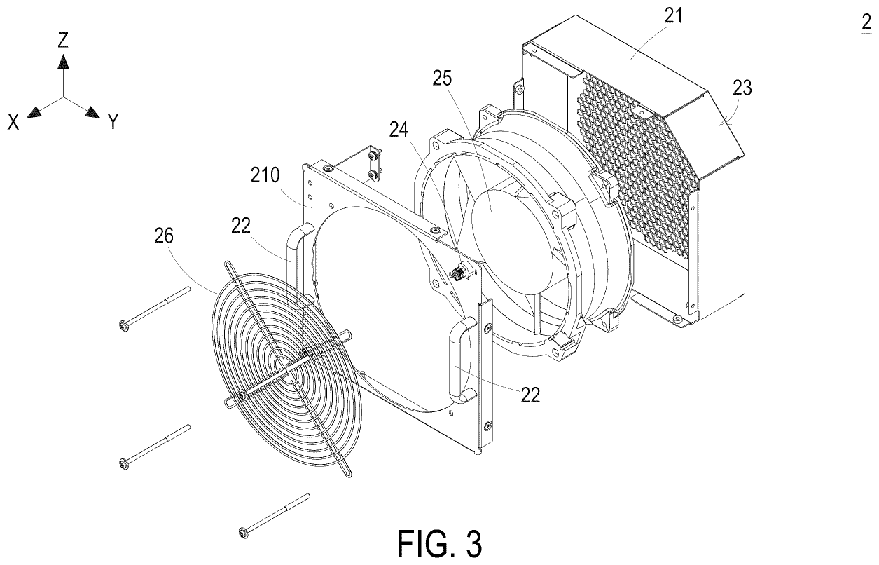

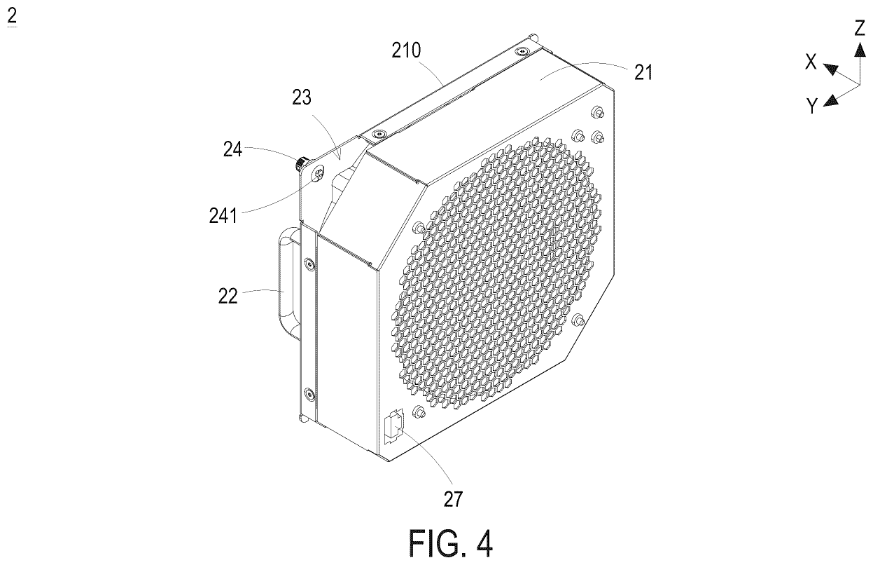

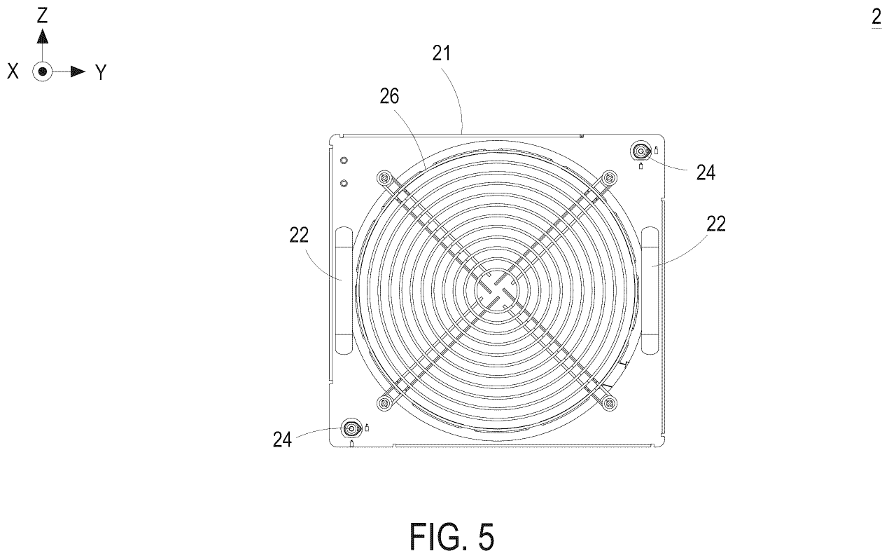

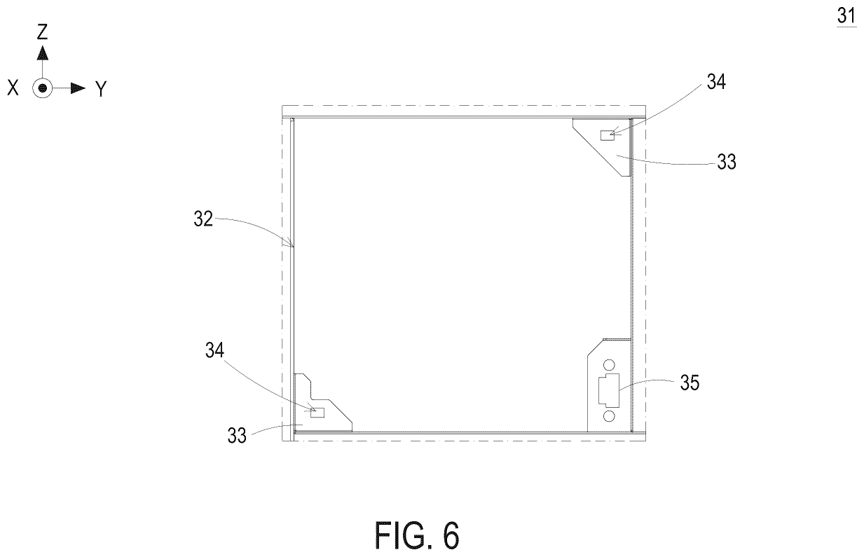

FIG. 1 is a perspective structural view illustrating a cooling cabinet according to an embodiment of the present disclosure. FIG. 2 is a perspective structural view illustrating the fan module corresponding to the mounting base according to the embodiment of the present disclosure. FIG. 3 is an exploded view illustrating the fan module according to the embodiment of the present disclosure. FIG. 4 is a perspective structural view illustrating the fan module according to the embodiment of the present disclosure and taken from the rear perspective. FIG. 5 is a front view illustrating the fan module according to the embodiment of the present disclosure. FIG. 6 is a front view illustrating the mounting base according to the embodiment of the present disclosure. Please refer to FIG. 1 to FIG. 6. In the embodiment, the present disclosure provides an air-assisted liquid cooling cabinet 1 used in a data center. The cooling cabinet 1 includes a cabinet 3, a plurality of fan modules 2 and a heat exchanger 4. The cabinet 3 includes a rear panel 30 and a plurality of mounting bases 31. The plurality of mounting bases 31 are arranged in an array on the rear panel 30 and in communication from an exterior of the cabinet 3 to an internal space of the cabinet 3. In the embodiment, each of the plurality of mounting bases 31 includes a square window 32, an alignment platform 33 and an engagement hole 34. Preferably but not exclusively, the alignment platforms 33 in pairs are disposed at the upper right and the lower left diagonally opposite corners of the square window 32. Preferably but not exclusively, the engagement holes 34 in pairs are correspondingly disposed on the alignment platforms 33 in pairs. The plurality of fan modules 2 are detachably disposed on the plurality of mounting bases 31. Each fan module 2 can be arbitrarily paired and connected with one of the plurality of mounting bases 31. In the embodiment, each of the plurality of fan modules 2 includes a square housing 21, an alignment recess 23 and an engagement component 24. The square housing 21 and the square window 32 of the mounting base 31 are matched to each other, and similar in appearance and outline. In addition, the alignment recesses 23 in pairs are disposed at the upper right and the lower left diagonally opposite corners of the square housing 21. Preferably but not exclusively, in the embodiment, the alignment recess 23 is formed by case trimming of two diagonally opposite conners of the square housing 21. The alignment recesses 23 in pairs are recessed from a rear side to a front side 210 of the square housing 21. Moreover, the alignment recess 23 is spatially corresponding to the alignment platform 33 of the mounting base 31. In the embodiment, two engagement components 24 are disposed in pairs, and each correspondingly runs through the alignment recess 23 from the front side 210 of the square housing 21. In the embodiment, when the alignment recess 23 and the alignment platform 33 are aligned with each other, the fan module 2 is allowed to be arbitrarily accommodated in a corresponding one of the plurality of mounting bases 31 along a docking direction (e.g., the inverse X-axis direction). Moreover, when the alignment recess 23 and the alignment platform 33 are matched with each other, the engagement component 24 is allowed rotating to engage with the engagement hole 34, so that the fan module 2 is locked on the corresponding one of the plurality of mounting bases 31. In the embodiment, the docking direction is perpendicular to the front side 210 of the square housing 21. Preferably but not exclusively, when the plurality of fan modules 2 are accommodated in the plurality of mounting bases 31 along the docking direction, respectively, the front side 210 of the square housing 21 is coplanar with the square window 32 of the corresponding mounting base 31. Certainly, the present disclosure is not limited thereto.

In the embodiment, the heat exchanger 4 is disposed in the cabinet 3. Preferably but not exclusively, the heat exchanger 4 is a heat exchanger for an air-assisted liquid cooling system, and configured to dissipate the heat generated by the coolant of the cold plate over a large area through multiple fan modules 2 cooperated with the heat exchanger 4. In the embodiment, when the plurality of fan modules 2 are enabled, gas is transported from the rear panel 30 into the internal space of the cabinet 3 to cool the heat exchanger 4. Certainly, the present disclosure is not limited thereto.

In the embodiment, the plurality of fan modules 2 are modularly designed and have the same structure. Each fan module 2 includes a main body 25 accommodated in the square housing 21 and in communication from the front to the rear. A grille 26 is provided on the front side 210 of the square housing 21 to protect the interior of the main body 25. Certainly, the internal structure of the fan module 2 is not an essential feature of the present disclosure, but adjustable according to the practical requirements, and not redundantly described hereafter. In the embodiment, each of the plurality of fan modules 2 includes a pair of handles 22 disposed on a front side 210 of the square housing 21 and parallel to two lateral sides of the square housing 21, for example, parallel to the Z-axis direction. Through the arrangement of the handles 22, the user can easily insert or remove the fan module 2 into or out of the mounting base 31. Notably, the plurality of fan modules 2 have the same modular structure and can be independently installed and arbitrarily connected to any one of the mounting bases 31 for use. In other words, through the modular design of the fan module 2, the maintenance of the cooling cabinet 1 or the replacement of the fan modules 2 can be simplified. The positioning, the electrical connection, the installation and the fixation required for assembly can be performed without the use of tools. The replace time is reduced sufficiently.

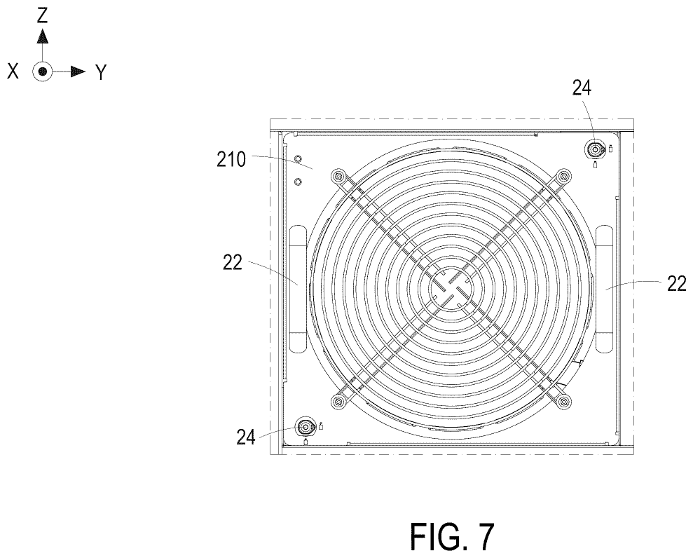

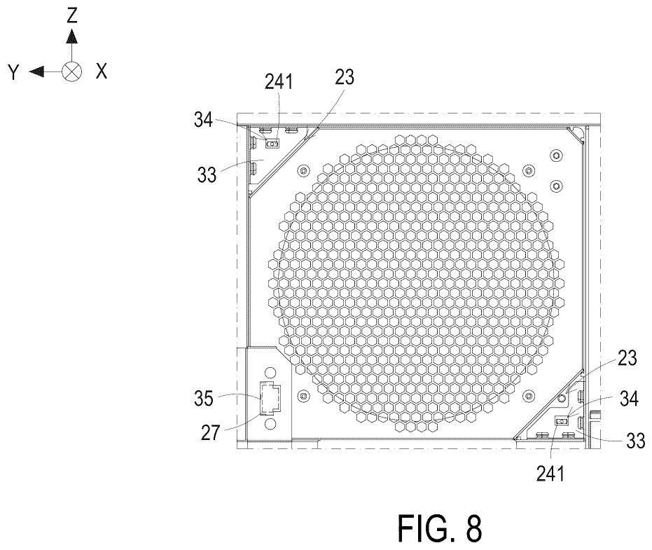

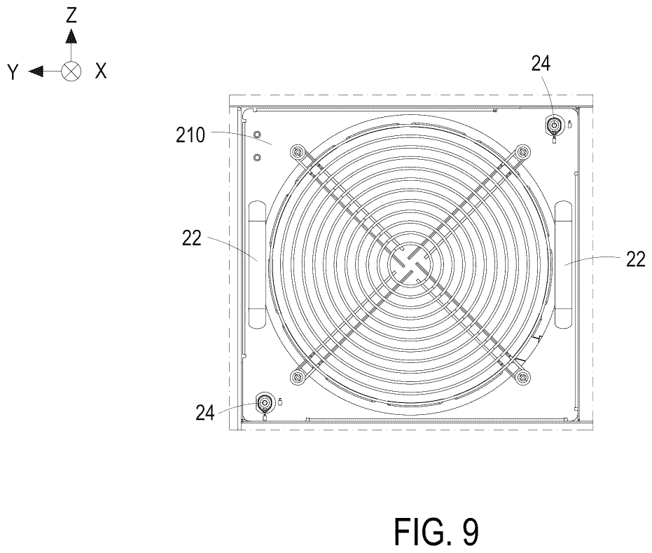

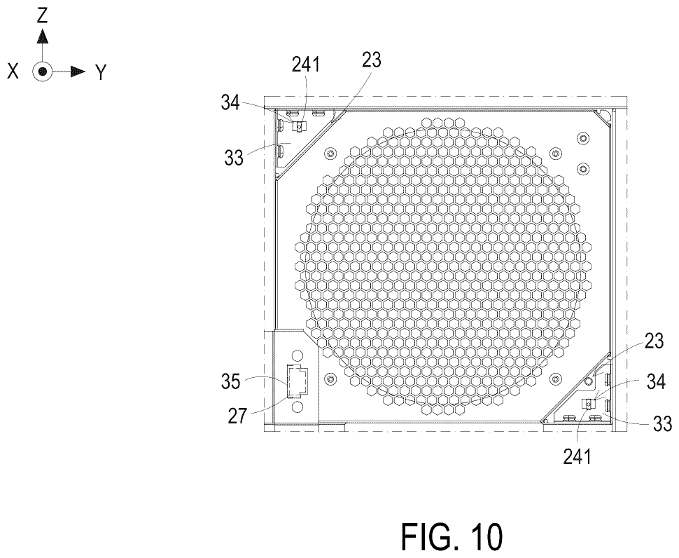

For the convenience of explanation, the positioning, the electrical connection, the installation and the fixation of one single fan module 2 and one corresponding mounting base 31 are described below. The present disclosure is not limited thereto. FIG. 7 is a front view illustrating the fan module accommodated in the mounting base and the engagement component is rotated to the unlocking position according to the embodiment of the present disclosure. FIG. 8 is a rear view illustrating the fan module accommodated in the mounting base and the engagement component is rotated to the unlocking position according to the embodiment of the present disclosure. FIG. 9 is a front view illustrating the fan module accommodated in the mounting base and the engagement component is rotated to the locking position according to the embodiment of the present disclosure. FIG. 10 is a rear view illustrating the fan module accommodated in the mounting base and the engagement component is rotated to the locking position according to the embodiment of the present disclosure. Please refer to FIG. 1 to FIG. 10. Preferably but not exclusively, in the embodiment, the engagement component 24 of the fan module 2 is a quarter turn lock with an engaging tail end 241. Preferably but not exclusively, the engagement hole 34 is a rectangular through hole. In the embodiment, a length of the engaging tail end 241 is shorter than a length of the engagement hole 34 and greater than a width of the engagement hole 34. When the user wants to install the fan module 2 into the mounting base 31, it allows the user holding the handle 22 with both hands to align the alignment recess 23 of the fan module 2 with the alignment platform 33 of the mounting base 31. Then the fan module 2 can be accommodated in the corresponding mounting base 31 along the docking direction (e.g., the inverse X-axis direction). At this time, the engagement component 24 of the fan module 2 needs to be rotated to an unlocking position, as shown in FIG. 7, so as to make the length direction of the engaging tail end 241 parallel to the length direction of the engagement hole 34. Since the length of the engaging tail end 241 is smaller than the length of the engagement hole 34, it allows the fan module 2 being pushed into the mounting base 31 along the docking direction (e.g., the inverse X-axis direction). It allows the engaging tail end 241 passing through the engagement hole 34, so that the alignment recess 23 of the fan module 2 is in contact with the alignment platform 33 of the mounting base 31, as shown in FIG. 8. Thereafter, it allows the user turning the engagement component 24, for example 90 degrees, so that the engaging tail end 241 of the engagement component 24 is rotated from the unlocking position to an unlocking position, as shown in FIG. 9. In this way, the engaging tail end 241 passing through the engagement hole 34 is rotated to make the length direction of the engaging tail end 241 perpendicular to the length direction of the engagement hole 34. Since the length of the engaging tail end 241 is greater than the width of the engagement hole 34, the engaging tail end 241 in the locked position interferes with the engagement hole 34, as shown in FIG. 10, so that the fan module 2 is locked in the corresponding mounting base 31.

On the contrary, when the user wants to detach the fan module 2 from the mounting base 31, it allows the user rotating the engagement component 24 from the locking position (as shown in FIG. 9) to the unlocking position (as shown in FIG. 7) Since the engaging tail end 241 in the unlocking position does not interfere with the engagement hole 34, it allows the user holding the handles 22 with both hands and removing the fan module 2 from the mounting base 31 along the opposite docking direction (i.e., the X-axis direction). In this way, the user can easily install the plurality of fan modules 2 into the plurality of mounting bases 31 on the rear panel 30 and remove the fan modules 2 for replacement or repair without the use of tools. The replace time is reduced sufficiently. Notably, the user may for example but not be limited to rotating the engagement component 24 to drive the engaging tail end 241 to rotate. Preferably but not exclusively, in other embodiments, the user can press down the engagement component 24 to drive the engaging tail end 241 to achieve the change between the locking position and the unlocking position. The present disclosure is not limited thereto.

Please refer to FIG. 1 to FIG. 10. In the embodiment, each of the modular mounting bases 31 further includes a first connector 35 disposed at a corner of the square window 32, as shown in FIG. 6. Preferably but not exclusively, the first connector 35 is located at the lower right corner, which is different from the two diagonally opposite corners where the alignment platforms 33 are located. In the embodiment, each of the modular fan modules 2 includes a second connector 27 disposed at a rear inclined corner of the square housing 21, as shown in FIG. 4. In the embodiment, the second connector 27 of the fan module 2 is spatially corresponding to the first connector 35 of the mounting base 31. Preferably but not exclusively, the first connector 35 and the second connector 27 are respectively a quick connector male terminal and a quick connector female terminal matched with each other. During installation, the user holds the handles 22 and pushes the fan module 2 into the mounting base 31 along the docking direction (i.e., the inverse X-axis direction). At the same time, the first connector 35 and the second connector 27 can be quickly connected (blind plug) to form an electrical connection. There is no need to manually connect the power or signal lines. Preferably but not exclusively, in the embodiment, either one of the first connector 35 and the second connector 27 can be designed as the male terminal of the quick connector, and the mal terminal of the quick connector allows slight movement. It helps to avoid damage caused by tolerances. Thereby, the plurality modular fan modules 2 on the cooling cabinet 1 can be easily and quickly installed and disassembled without the use of tools.

Notably, in in the foregoing description of the embodiment, the number and the arrangement of the alignment recess 23, the alignment platform 33, the engagement component 24, the engagement 34, the first connector 35 and the second connector 27 are adjustable according to the sizes of the square housing 21 and the square window 32, or adjustable according to the practical requirements. The present disclosure is not limited thereto and not redundantly described hereafter.

In summary, the present disclosure provides a cooling cabinet and a fan module thereof. The fan module has the structure with a modular design to simplify the maintenance of the cooling cabinet or the replacement of the fan module, and it allows performing the positioning, the power connection and the installation and fixation of the assembly without tools, so as to reduce the replacement time sufficiently. A plurality of fan modules with modular design structures allow simple and fast installation in a plurality of mounting bases on the rear panel of the cooling cabinet, and corresponding to the heat exchanger in the cabinet to realize the application of the air-assisted liquid cooling cabinet. A pair of handles are disposed on a front side of the square housing of each fan module, so that the fan module can be easily lifted, installed or removed. An alignment recess is disposed at two diagonally opposite corners of the square housing, and spatially corresponding to the alignment platform of the mounting base, so that the fan module can be placed into the corresponding mounting base. In addition, the engagement component includes a quarter turn lock, which runs through the front side of the square housing to the alignment recess and corresponds to the engagement hole on the alignment platform. When the fan module is accommodated into the corresponding mounting base through the handles by the user, it allows the user turning the engagement component on the front side of the square housing, for example 90 degrees, or pressing down the engagement component to be engaged or loosened with the engagement hole. Then the fan module is firmly locked on the corresponding mounting base or detached from the mounting base. The alignment recess is formed by case trimming of the square housing, and the square housing allows to include any shape of the chamfered corners corresponding to the alignment platform. It prevents the user from damaging the fan module due to the wrong installation direction when placing the fan module into the mounting base. In addition, the pairing of the alignment recess and the alignment platform can be realized in a recessed push-in manner, and it makes positioning easier. The electrical connection design between the fan module and the mounting base of the cabinet is implemented by using the quick connector (blind plug) terminals. During installation, the user holds the handles and pushes the fan module into the mounting base. At the same time, the quick connector (blind plug) also completes the electrical connection. There is no need to manually connect the power or signal lines. In addition, the male terminal of the quick connector is designed to allow slight movement, and it helps to avoid damage caused by tolerances. In this way, the plurality modular fan modules on the cooling cabinet can be easily and quickly installed and disassembled without the use of tools. The present disclosure includes the industrial applicability and the inventive steps.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A cooling cabinet, comprising:
a cabinet, comprising a rear panel and a plurality of mounting bases, wherein the plurality of mounting bases are arranged in an array on the rear panel and in communication from an exterior of the cabinet to an internal space of the cabinet, wherein each of the plurality of mounting bases comprises a square window, an alignment platform and an engagement hole, the alignment platform is disposed at two diagonally opposite corners of the square window, and the engagement hole is correspondingly disposed on the alignment platform;
a plurality of fan modules detachably disposed on the plurality of mounting bases, wherein the each of the plurality of fan modules comprises a square housing, an alignment recess and an engagement component, wherein the square housing and the square window are matched to each other, the alignment recess is disposed at two diagonally opposite corners of the square housing, and recessed from a rear side to a front side of the square housing, the alignment recess is spatially corresponding to the alignment platform of the mounting base, and the engagement component runs through the alignment recess from the front side of the square housing, wherein when the alignment recess and the alignment platform are aligned with each other, the fan module is allowed to be accommodated in a corresponding one of the plurality of mounting bases along a docking direction, wherein when the alignment recess and the alignment platform are matched with each other, the engagement component is allowed rotating to engage with the engagement hole, so that the fan module is locked on the corresponding one of the plurality of mounting bases; and
a heat exchanger disposed in the cabinet; wherein when the plurality of fan modules are enabled, gas is transported from the rear panel into the internal space of the cabinet to cool the heat exchanger.

2. The cooling cabinet according to claim 1, wherein the cooling cabinet is an air-assisted liquid cooling cabinet used in a data center.

3. The cooling cabinet according to claim 1, wherein each of the plurality of fan modules comprises a pair of handles disposed on a front side of the square housing and parallel to two lateral sides of the square housing.

4. The cooling cabinet according to claim 1, wherein the docking direction is perpendicular to a front side of the square housing, wherein when the plurality of fan modules are accommodated in the plurality of mounting bases along the docking direction, respectively, the front side of the square housing is coplanar with the square window.

5. The cooling cabinet according to claim 1, wherein the engagement component is a quarter turn lock with an engaging tail end, wherein a length of the engaging tail end is shorter than a length of the engagement hole and greater than a width of the engagement hole.

6. The cooling cabinet according to claim 5, wherein when the alignment recess is aligned with the alignment platform and allows the fan module to be accommodated in the corresponding one of the plurality of mounting bases along the docking direction, the engagement component is rotated to an unlocking position, and the engaging tail end allows passing through the engagement hole to make the alignment recess butt the alignment platform.

7. The cooling cabinet according to claim 6, wherein when the fan module is accommodated in the corresponding one of the plurality of mounting bases along the docking direction and the alignment recess butts the alignment platform, the engagement component is rotated from the unlocking position to a locking position, and the engaging tail end and the engagement hole are interfered with each other to lock the fan module in the corresponding one of the plurality mounting bases.

8. The cooling cabinet according to claim 1, wherein the alignment recess is formed by two opposite chamfered corners of the square housing.

9. The cooling cabinet according to claim 1, wherein each of the plurality of mounting bases comprises a first connector disposed at a corner of the square window, each of the plurality of fan modules comprises a second connector disposed at a rear side of the square housing, and the second connector is spatially corresponding to the first connector, wherein when the fan module is accommodated in the corresponding one of the plurality of mounting bases along the docking direction, the first connector and the second connector are connected to form an electrical connection.

10. The cooling cabinet according to claim 9, wherein the first connector and the second connector are respectively a quick connector male terminal and a quick connector female terminal matched with each other.

11. A fan module, detachably disposed on a mounting base, wherein the mounting base comprises a square window, an alignment platform and an engagement hole, the alignment platform is disposed at two diagonally opposite corners of the square window, the engagement holes are disposed on the alignment platform, and the fan module comprises:
a square housing, matched with the square window;
an alignment recess, wherein the alignment recess is disposed at two diagonally opposite corners of the square housing, and recessed from a rear side to a front side of the square housing, and the alignment recess is spatially corresponding to the alignment platform of the mounting base; and
an engagement component, wherein the engagement component runs through the alignment recess from the front side of the square housing, wherein when the alignment recess and the alignment platform are aligned with each other, the fan module is allowed to be accommodated in the mounting base along a docking direction, wherein when the alignment recess and the alignment platform are matched with each other, the engagement component is allowed rotating to engage with the engagement hole, so that the fan module is locked on the mounting base.

12. The fan module according to claim 11, wherein the fan module comprises a pair of handles disposed on a front side of the square housing and parallel to two lateral sides of the square housing.

13. The fan module according to claim 11, wherein the docking direction is perpendicular to a front side of the square housing, wherein when the fan module is accommodated in the mounting base along the docking direction, the front side of the square housing is coplanar with the square window.

14. The fan module according to claim 11, wherein the engagement component is a quarter turn lock with an engaging tail end, wherein a length of the engaging tail end is shorter than a length of the engagement hole and greater than a width of the engagement hole.

15. The fan module according to claim 14, wherein when the alignment recess is aligned with the alignment platform and allows the fan module to be accommodated in the mounting base along the docking direction, the engagement component is rotated to an unlocking position, and the engaging tail end allows passing through the engagement hole to make the alignment recess butt the alignment platform.

16. The fan module according to claim 15, wherein when the fan module is accommodated in the mounting base along the docking direction and the alignment recess butts the alignment platform, the engagement component is rotated from the unlocking position to a locking position, and the engaging tail end and the engagement hole are interfered with each other to lock the fan module in the mounting base.

17. The fan module according to claim 11, wherein the alignment recess is formed by two opposite chamfered corners of the square housing.

18. The fan module according to claim 11, wherein the mounting base comprises a first connector disposed at a corner of the square window, the fan module comprises a second connector disposed at a rear side of the square housing, and the second connector is spatially corresponding to the first connector, wherein when the fan module is accommodated in the mounting base along the docking direction, the first connector and the second connector are connected to form an electrical connection.

19. The fan module according to claim 18, wherein the first connector and the second connector are respectively a quick connector male terminal and a quick connector female terminal matched with each other.
